(19) United States
(12) Patent Application Publication
(10) Pub. No.: US 2015/0144903 A1
(43) Pub. Date: May 28, 2015

(54) ORGANIC LIGHT EMITTING DIODE DEVICE

(71) Applicant: SAMSUNG DISPLAY CO., LTD., Yongin-City (KR)

(72) Inventors: Seok Gyu YOON, Hwaseong-si (KR); Dong Chan KIM, Hwaseong-si (KR); Eung Do KIM, Seoul (KR); Dong Kyu SEO, Suwon-si (KR); Bo Ra JUNG, Seoul (KR); Kyu Hwan HWANG, Yongin-si (KR); Won-Jong KIM, Suwon-si (KR); Young-Woo SONG, Suwon-si (KR); Jong Hyuk LEE, Seoul (KR)

(21) Appl. No.: 14/459,576

(22) Filed: Aug. 14, 2014

(30) Foreign Application Priority Data
Nov. 25, 2013 (KR) 10-2013-0144003

(51) Int. Cl. H01L 51/52; H01L 51/50

(52) U.S. Cl. CPC H01L 51/5203; H01L 51/5092; H01L 51/5262
USPC 257/40

(57) ABSTRACT

An organic light emitting diode device includes an emission layer between first and second electrodes, a first auxiliary layer, and a second auxiliary layer. The first electrode includes a silver-magnesium alloy having a greater content of silver than magnesium. The first auxiliary layer is between the first electrode and emission layer, and includes an inorganic material. The second auxiliary layer is between the first electrode and first auxiliary layer, and includes a material having a work function of less than or equal to about 4.0 eV.

### CROSS-REFERENCE TO RELATED APPLICATION

Korean Patent Application No. 10-2013-0144003 filed on Nov. 25, 2013, and entitled, “ORGANIC LIGHT EMITTING DIODE DEVICE,” is incorporated by reference herein in its entirety.

### BACKGROUND 1. Field

One or more embodiments described here relate to a display device.

2. Description of the Related Art

A variety of flat panel displays have been developed with reduced size compared with cathode ray tube (CRT) displays. Examples include liquid crystal displays and organic light emitting displays. In order to output a visible image, liquid crystal displays require a separate backlight. Also, this type of display is limited in terms of response speed and viewing angle.

Organic light emitting displays use organic light emitting diodes (OLEDs) to emit light for purposes of generating an image. Each OLED includes an emission layer between two electrodes. Each OLED emits light based on excitons, which are formed when electrons injected from one electrode are combined with holes injected from the other electrode.

### SUMMARY

In accordance with one embodiment, an organic light emitting diode device includes a first electrode including a silver-magnesium alloy having a greater content of silver than magnesium; a second electrode facing the first electrode; an emission layer between the first and second electrodes; a first auxiliary layer between the first electrode and the emission layer and including an inorganic material, and a second auxiliary layer between the first electrode and first auxiliary layer and including a material having a work function of less than or equal to about 4.0 eV.

The inorganic material may include a metal oxide. The inorganic material may include WO₃, Li₂O, or a combination thereof. The first auxiliary layer may include an organic material. The first auxiliary layer may have a thickness of about 300 Å to 500 Å. The material having a work function of less than or equal to about 4.0 eV may be at least one of ytterbium (Yb), samarium (Sm), lanthanum (La), yttrium (Y), calcium (Ca), strontium (Sr), cesium (Cs), ruthenium (Ru), or barium (Ba). The material having a work function of less than or equal to about 4.0 eV may be ytterbium (Yb).

The second auxiliary layer may include an electron injection material. The electron injection material may be at least one of LiF, NaF, NaCl, CsF, BaO, lithium quinolate, or a combination thereof.

The material having a work function of less than or equal to about 4.0 eV and the electron injection material may be included in a weight ratio of about 100:1 to about 1:100. The second auxiliary layer may have a thickness of about 5 Å to about 50 Å.

The magnesium may be in an amount of less than or equal to about 30% by volume based on a total amount of the alloy. The magnesium may be in an amount of about 5% by volume to about 30% by volume based on the total amount of the alloy. A mixing ratio of the magnesium and silver may be about 1:8 to about 1:12.

The first electrode may have a thickness of about 30 Å to about 300 Å. The first electrode may have a light transmittance of about 50% to about 90% at a wavelength of about 500 nm to about 600 nm.

In accordance with another embodiment, an organic light emitting diode includes a first electrode; a second electrode facing the first electrode; an emission layer between the first and second electrodes; a first auxiliary layer between the first electrode and emission layer, and a second auxiliary layer between the first electrode and first auxiliary layer, wherein the second auxiliary layer includes an inorganic material and wherein the second auxiliary layer includes a material having a work function of less than or equal to about 4.0 eV. The first electrode may include a silver-magnesium alloy having a greater content of silver than magnesium.

The material having a work function of less than or equal to about 4.0 eV may be at least one of ytterbium (Yb), samarium (Sm), lanthanum (La), yttrium (Y), calcium (Ca), strontium (Sr), cesium (Cs), ruthenium (Ru), or barium (Ba). The first auxiliary layer may include an organic material.

### BRIEF DESCRIPTION OF THE DRAWINGS

Features will become apparent to those of skill in the art by describing in detail exemplary embodiments with reference to the attached drawings in which:

FIG. 1 illustrates an embodiment of an organic light emitting diode device;

FIG. 2 illustrates examples of light absorption rates of the organic light emitting diode device with comparative examples;

FIG. 3 illustrates examples of light absorption rates and light transmittances of the organic light emitting diode device with a comparative example;

FIG. 4 is a photograph of an example of an OLED panel; and

FIG. 5 is a photograph of an OLED panel according to a comparative example.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

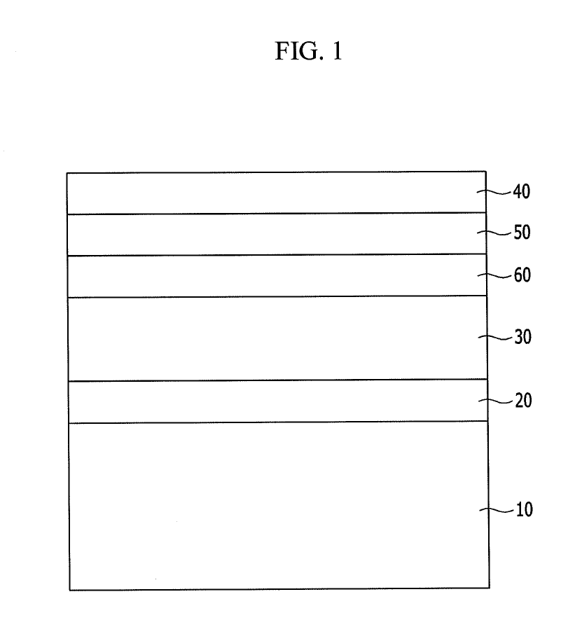

FIG. 1 illustrates an embodiment of an organic light emitting diode display which includes a substrate 10, a lower electrode 20, an upper electrode 40 facing the lower electrode 20, and an emission layer 30 between lower electrode 20 and upper electrode 40. In one embodiment, these features may form an organic light emitting diode of a pixel in the display device.

The substrate 10 may be made of an inorganic material such as glass or an organic material. Examples of an organic material include polycarbonate, polymethylmethacrylate, polyethyleneterephthalate, polyethylenenaphthalate, polyamide, polyethersulfone, or a combination thereof, or silicon wafer.

One of the lower electrode 20 or the upper electrode 40 is a cathode, and the other is an anode. For example, the lower electrode 20 may be an anode and upper electrode 40 may be a cathode. At least one of the lower electrode 20 or upper electrode 40 may be a transparent electrode, When the lower electrode 20 is a transparent electrode, bottom emission of emitting light toward substrate 10 may be realized. When the upper electrode 40 is a transparent electrode, top emission of emitting light toward the opposite side of the substrate 10 may be realized. In addition, when lower electrode 20 and upper electrode 40 are both transparent electrodes, emission of light from both sides, towards the substrate 10 and opposite side of the substrate 10, is realized.

The transparent electrode may be made to include silver (Ag)-magnesium (Mg) alloy. Silver (Ag) is a metal having high electricity conductivity, but low light absorption rate. Use of such a metal may therefore improve electrical characteristics and optical properties. Magnesium (Mg) is a metal having a low work function. Use of this metal may improve charge mobility and increase the strength of an electrode thin film, and thus overall reliability of the device.

The silver (Ag)-magnesium (Mg) alloy may be a silver (Ag)-rich alloy including more silver (Ag) than magnesium (Mg).

The magnesium may be included in an amount of less than or equal to about 30% by volume based on the total amount of silver (Ag)-magnesium (Mg) alloy. When magnesium is included within this range, device efficiency is improved by securing stability of the electrode thin film, increasing light transmittance, and decreasing light absorption rate. Magnesium may be included in an amount of about 5% by volume to about 30% by volume within the range based on the total amount of the silver (Ag)-magnesium (Mg) alloy.

The magnesium (Mg) may be mixed with silver (Ag) in a ratio of about 1:8 to about 1:12. In one embodiment, the missing ratio may be about 1:9 to about 1:11 within the aforementioned range. When magnesium is mixed with silver within this ratio range, a silver (Ag)-magnesium (Mg) alloy may be easily obtained to improve device efficiency.

The transparent electrode may have a thickness of about 30 Å to about 300 Å. When the transparent electrode has a thickness within this range, device efficiency may be improved by increasing light transmittance and decreasing light absorption rate.

The transparent electrode may have light transmittance ranging from about 50% to about 90%. In one embodiment, the range may include about 65% to about 85% in a visible ray region of about 550 nm, for example, in a wavelength region ranging from about 500 nm to about 600 nm. The transparent electrode has light transmittance within this range and may increase light efficiency of eternally emitted light.

When the lower electrode 20 and upper electrode 40 are transparent electrodes, one may be made of the aforementioned silver (Ag)-magnesium (Mg) alloy. The other may be made of the aforementioned silver (Ag)-magnesium (Mg) alloy or a transparent conductive oxide. The transparent conductive oxide may be, for example, an indium tin oxide (ITO) or indium zinc oxide (IZO).

When one of the lower electrode 20 or the upper electrode 40 is a transparent electrode, the transparent electrode may be made of the aforementioned silver (Ag)-magnesium (Mg) alloy. The other may be made of a reflective electrode made of an opaque conductor. The opaque conductor may include, for example, a metal such as aluminum (Al), copper (Cu), molybdenum (Mo), silver (Ag), an alloy thereof, or a combination thereof. For example, the upper electrode 40 may be a cathode and may be a transparent electrode made of the aforementioned silver (Ag)-magnesium (Mg) alloy.

The emission layer 30 may be made of an organic material emitting light of a primary color such as red, green, blue. In an alternative embodiment, the emission layer 30 may be made of a mixture of an inorganic material with the organic material. Examples include a polyfluorene derivative, a (poly)paraphenylenevinylene derivative, a polyphenylene derivative, a polyfluorene derivative, polyvinylcarbazole, a polythiophene derivative, or a compound prepared by doping these polymer materials with a perylene-based pigment, a cumarine-based pigment, a rothermine-based a pigment, rubrene, perylene, 9,10-diphenylanthracene, tetraphenylbutadiene, Nile red, coumarin, quinacridone, and the like. The organic light emitting diode device may display an image through a spatial sum of basic colors emitted from the emission layer.

The emission layer 30 may emit white light based on a combination of primary colors (e.g., red, green, and blue light). The combination of colors may be implemented by combination of adjacent sub-pixels to emit white, or a stack in a vertical direction to emit white.

In order to improve luminous efficiency of the emission layer 30, a lower auxiliary layer 60 and upper auxiliary layer 50 may be interposed between the emission layer 30 and the upper electrode 40. In one embodiment, the lower auxiliary layer 60 and upper auxiliary layer 50 may be located between the emission layer 30 and the lower electrode 40. In another embodiment one or both of the auxiliary layers may be interposed between the emission layer 30 and the upper electrode 20, between the emission layer 30 and the upper electrode 40, and/or between the emission layer 30 and the lower electrode 20.

The lower auxiliary layer 60 may include an inorganic material, and thus may suppress a metallic material in the upper electrode 40 from being diffused into a lower layer (e.g., emission layer 30) during formation of the upper electrode 40 and/or operation of the organic light emitting diode device.

The lower auxiliary layer 60 may include, for example, a metal oxide. The metal oxide may be, for example, WO₃, Li₂O, or a combination thereof. The lower auxiliary layer 60 may be, for example, about 300 Å to about 500 Å thick. When the lower auxiliary layer 60 has a thickness in this range, the lower auxiliary layer 60 may suppress a metallic material from being diffused into a lower layer and may decrease generation of a dark spot in the emission layer.

For example, when an electric field is applied to an organic light emitting diode device, a metallic material in the upper electrode 40 may be randomly diffused into a lower layer. The diffused metallic material and the lower electrode 20 may become closer, and thus the electric field may become strong at a predetermined distance of the emission layer 30. In this way, a dark spot (e.g., a spot which looks darker than others areas) may be generated where the electric field is strongly applied. This effect may deteriorate characteristics of the display.

According to the embodiment, the lower auxiliary layer 60 including an inorganic material is interposed between the upper electrode 40 and the emission layer 30. In this configuration, the inorganic material may bond with a metallic material in the form of ions diffused into a lower layer, and thus may prevent the metallic material from being further diffused. Particularly, a metal oxide (e.g., WO₃, Li₂O, or a combination thereof) may form a stronger bond with the metallic material, and thus may decrease generation of a dark spot.

The lower auxiliary layer 60 may further include an organic material to balance electrons and holes. The organic material may be, for example an oxadiazole derivative, benzoquinone or a derivative thereof, a metallic complex of anthraquinone or a derivative thereof, 8-hydroxyquinoline or a derivative thereof, polyquinoline or a derivative thereof, polyquinoxaline or a derivative thereof, polyfluorene or a derivative thereof, and the like, but is not limited thereto. For example, the organic material may be 2-(4-biphenylyl)-5-(4-t-butylphenyl)-1,3,4-oxadiazole, benzoquinone, anthraquinone, or tris(8-quinolinyl)aluminum, polyquinoline.

The upper auxiliary layer 50 may include a material having a work function of less than or equal to about 4.0 eV. The material having a work function of less than or equal to about 4.0 eV may be at least one selected from, for example ytterbium (Yb), samarium (Sm), lanthanum (La), yttrium (Y), calcium (Ca), strontium (Sr), cesium (Cs), ruthenium (Ru), or barium (Ba). For example, the material having a work function of less than or equal to about 4.0 eV may be ytterbium (Yb). Ytterbium (Yb) has a relatively low work function. Also, Ytterbium (Yb) may decrease a driving voltage because electrons may be easily injected into emission layer 30. In addition, ytterbium (Yb) has a low absorption rate and may improve light transmittance.

The upper auxiliary layer 50 may have, for example, a thickness of about 5 Å to about 50 Å. When the upper auxiliary layer 50 has a thickness in this range, light transmittance as well as charge mobility may be increased. Thus, device efficiency may be improved.

The upper auxiliary layer 50 may further include an electron injection material. The electron injection material may include, for example, an oxide of an alkaline metal or an alkaline-earth metal, fluoride, quinolate, an acetoacetate compound, or a combination thereof. For example, the electron injection material may be at least one of LiF, NaF, NaCl, CsF, BaO, lithium quinolate, or a combination thereof.

The upper auxiliary layer 50 may include a material having a work function of less than or equal to about 4.0 eV and an electron injection material. The material having a work function of less than or equal to about 4.0 eV and the electron injection material may be, for example, codeposited. The electron transport layer (ETL) 60 simultaneously includes the material having a work function of less than or equal to about 4.0 eV and the electron injection material, so that electrons may be more smoothly injected.

The material having a work function of less than or equal to about 4.0 eV and the electron injection material may be included in a weight ratio of about 100:1 to about 1:100. When the material having a work function of less than or equal to about 4.0 eV and the electron injection material are included in this range, electrons may be more smoothly injected.

### MANUFACTURE OF ORGANIC LIGHT EMITTING DIODE DEVICE

### Example 1

In Example 1, ITO (anode) was laminated and patterned on a glass substrate. NPB (N,N-dinaphthalene-1-yl_N,N-diphenyl benzidine) was deposited thereon. An emission layer was formed by co-depositing Alq3 (tris 8-hydroquinoline aluminum) doped with 1 wt % of coumarin 6. A first auxiliary layer was formed thereon by depositing WO₃. Subsequently, ytterbium (Yb) and LiF (1:1 of a volume ratio) were co-deposited thereon to be 20 Å thick to form a second auxiliary layer. Silver (Ag) and magnesium (Mg) in a ratio of 10:1 (vol %) were thermally deposited to be 100 Å thick to form a cathode.

### Example 2

In Example 2, an organic light emitting diode device was manufactured according to the same method as Example 1, except Li₂O was used instead of WO₃.

### Comparative Example 1

In Comparative Example 1, an organic light emitting diode device was manufactured according to the same method as Example 1, except the first auxiliary layer was not deposited.

### Comparative Example 2

In Comparative Example 2, an organic light emitting diode device was manufactured according to the same method as Example 1, except Liq was deposited instead of WO₃.

### Comparative Example 3

In Comparative Example 3, an organic light emitting diode device was manufactured according to the same method as Example 1, except silver (Ag) and magnesium (Mg) were used in a ratio of 1:10 (vol %).

### Comparative Example 4

In Comparative Example 4, an organic light emitting diode device was manufactured according to the same method as Example 1, except ytterbium (Yb) was not used.

### Evaluation 1: Generation Degree of Dark Spot

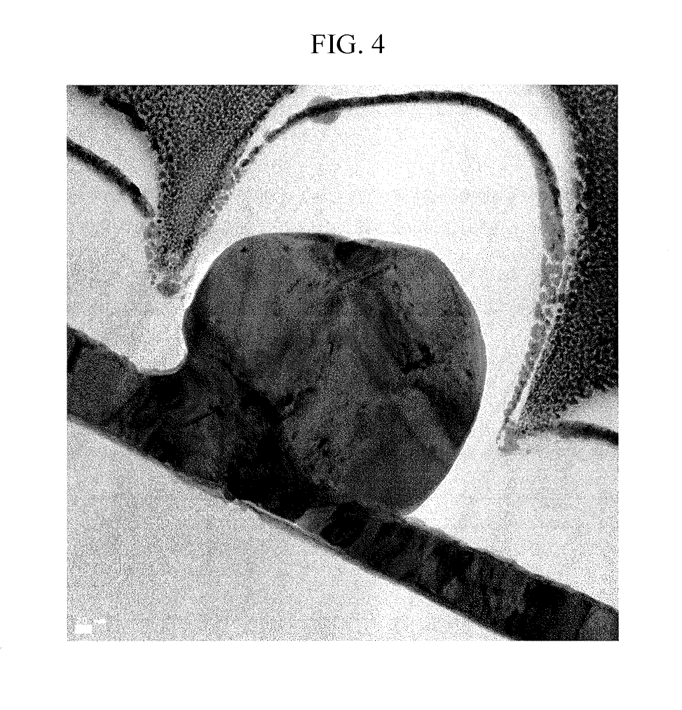

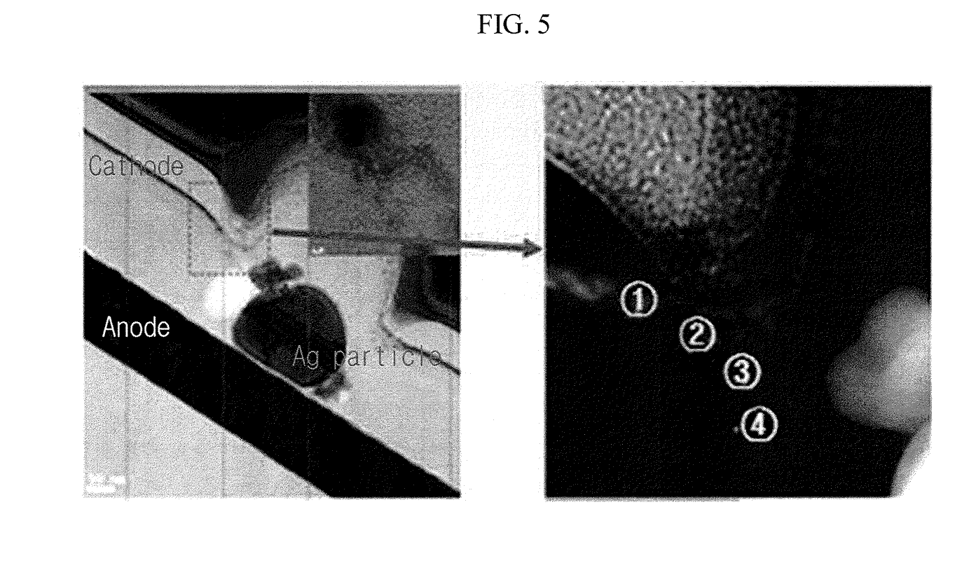

A degree of generating a dark spot in the organic light emitting diode devices according to Example 1 and Comparative Example 2 was measured. The measurement was performed by taking a tunneling electron microscope (TEM) photograph of a region where a dark spot is generated in an OLED panel. The results are provided in FIGS. 4 and 5.

FIG. 4 is a TEM photograph of an OLED panel according to Example 1, and FIG. 5 is a TEM photograph of an OLED panel according to Comparative Example 2. Referring to FIGS. 4 and 5, the organic light emitting diode device according to Example 1 showed almost no dark spot generation compared with the organic light emitting diode device according to Comparative Example 2. The reason is that the first auxiliary layer including an inorganic material in the organic light emitting diode device according to Example 1 minimized a degree of generating a dark spot. Inorganic material, WO₃ in the first auxiliary layer formed a strong bond with a cathode material as an ion, and thus did not suppress diffusion of the cathode material in Example 1. In contrast, organic material (Liq) did not form a strong bond with the cathode material as an ion and made the cathode material diffused in Comparative Example 2.

The following Table 1 shows composition analysis results obtained by enlarging a dark spot region in FIG. 5.

TABLE 1

| | \textcircled{1} | \textcircled{2} | \textcircled{3} | \textcircled{4} |
|---|---|---|---|---|
| Mg (at. %) | 59.2 | 20.6 | 5.7 | 0.5 |
| Ag (at. %) | 40.8 | 79.4 | 94.3 | 2.5 |
| C (at. %) | — | — | — | 97.0 |

As shown in Table 1, the Ag and Mg electrode material formed an island and formed toward an Ag particle. Accordingly, the Ag and Mg was to be suppressed from diffusing using a material which plays the role of a blocking layer. As shown in FIG. 4, the inorganic material of Example 1 played the role of suppressing diffusion of the Ag and Mg.

### Evaluation 2: Light Transmittance, Light Absorption Rate

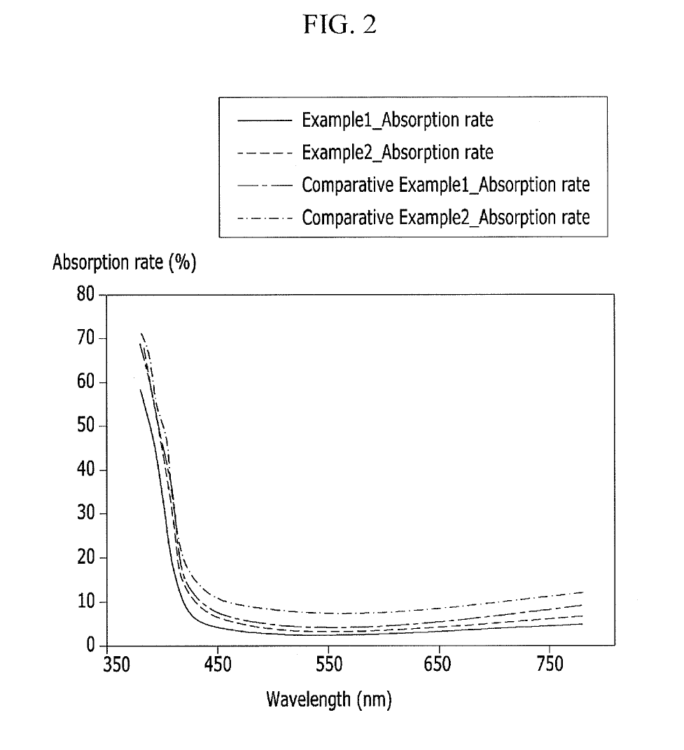

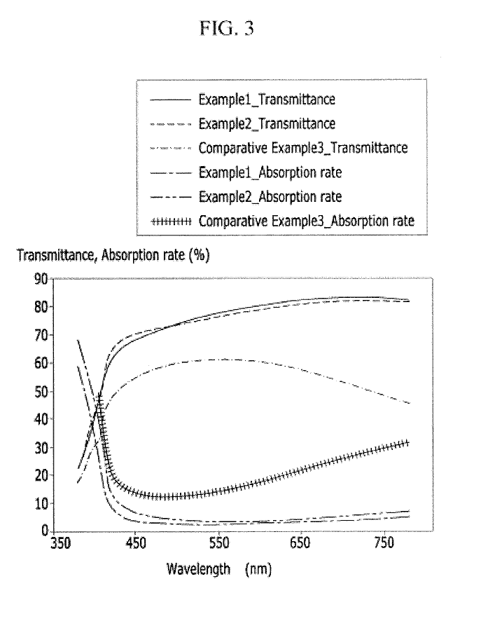

The light transmittance and light absorption rate of organic light emitting diode devices according to Examples 1 and 2 and Comparative Example 3 were measured. The measurement was performed in an UV-visible spectrophotometery method. The results are provided in FIGS. 2 and 3.

FIG. 2 is a graph showing light absorption rate of the organic light emitting diode devices according to Examples 1 and 2 and Comparative Examples 1 and 2. FIG. 3 is a graph showing light transmittance and light absorption rate of the organic light emitting diode devices according to Examples 1 and 2 and Comparative Example 3.

Referring to FIGS. 2 and 3, the organic light emitting diode devices according to Examples 1 and 2 showed a lower light absorption rate than the organic light emitting diode devices according to Comparative Examples 1 to 3. In particular, the organic light emitting diode devices according to Examples 1 and 2 showed higher light transmittance and lower light absorption rate than the organic light emitting diode device according to Comparative Example 3.

Accordingly, the light transmittance of the organic light emitting diode devices according to Examples 1 and 2 was improved due to a silver (Ag)-magnesium (Mg) alloy electrode. This electrode decreased the amount of absorbed light and improved efficiency. Particularly, the silver (Ag)-magnesium (Mg) alloy electrode of the organic light emitting diode devices according to Examples 1 and 2 showed light transmittance ranging from about 50% to 90% (e.g., about 65% to 85%) with a reference to about 500 nm to 600 nm (e.g., 550 nm).

### Evaluation 3: Driving Voltage, Luminance, Efficiency and Life-Span Characteristic

A driving voltage, luminance, efficiency, and life-span characteristics of the organic light emitting diode devices according to Example 1 and Comparative Example 4 were measured. The voltage and efficiency were measured using a current-voltage meter (Keithley 2400), luminance was measured using a luminance meter (Minolta Cs-1000A), and life-span was obtained by determining how long it took for initial luminance to decrease by 90%, relative to initial luminance. The measurement results are provided in the following Table 2.

TABLE 2

| | | | Current | | | Life-span |
|---|---|---|---|---|---|---|
| | Auxiliary | Driving | density | Effi- | Light | (hr@ |
| | layer | voltage | (mA/ | ciency | emitting | 10 mA/ |
| | material | (V) | cm²) | (cd/A) | color | cm²) |
| Example 1 | ytterbium | 4.8 | 10 | 3.96 | blue | 195 hr |
| | (Yb) and | | | | | |
| | LiF (1:1 | | | | | |
| | volume | | | | | |
| | ratio) | | | | | |
| Comparative | LiF | 4.9 | 10 | 3.80 | blue | 192 hr |
| Example 4 | | | | | | |

As shown in Table 2, the organic light emitting diode device using ‘ytterbium (Yb) and LiF (1:1 volume ratio)’ as an auxiliary layer material according to Example 1 showed excellent driving voltage, luminance, efficiency, and life-span characteristics compared with the organic light emitting diode device using only ‘LiF’.

As shown in Evaluations 1 to 3, light transmittance of the organic light emitting diode device was improved using the first auxiliary layer including an inorganic material (e.g., WO₃) to prevent generation of a dark spot. An improvement was also realized by using a first electrode which includes silver-magnesium alloy having more magnesium than silver. Also, the efficiency and life-span characteristics of the organic light emitting diode device were improved using a material having a work function of less than or equal to about 4.0 eV such as ytterbium.

By way of summation and review, organic light emitting displays use organic light emitting diodes to emit light for purposes of generating an image. Each OLED includes an emission layer between two electrodes. Also, each OLED emits light based on excitons, which are formed when electrons injected from one electrode are combined with holes injected from the other electrode. The light emitted from the emission layer is externally released through at least one of the two electrodes.

In accordance with one or more of the aforementioned embodiments, it is recognized that optical properties of the electrodes may have an influence on efficiency of the organic light emitting diode device. Accordingly, an organic light emitting diode device is provided which has excellent light-emitting efficiency achieved by lowering a light absorption rate of an electrode and minimizing generation of a dark spot by suppressing diffusion of an electrode material. For example, in one embodiment the electron injection layer includes Yb.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

What is claimed is:

1. An organic light emitting diode device, comprising
a first electrode including a silver-magnesium alloy having a greater content of silver than magnesium;
a second electrode facing the first electrode;
an emission layer between the first and second electrodes;
a first auxiliary layer between the first electrode and the emission layer and including an inorganic material, and
a second auxiliary layer between the first electrode and first auxiliary layer and including a material having a work function of less than or equal to about 4.0 eV.

2. The device as claimed in claim 1, wherein the inorganic material includes a metal oxide.

3. The device as claimed in claim 2, wherein the inorganic material includes WO₃, Li₂O, or a combination thereof.

4. The device as claimed in claim 1, wherein the first auxiliary layer includes an organic material.

5. The device as claimed in claim 1, wherein the first auxiliary layer has a thickness of about 300 Å to 500 Å.

6. The device as claimed in claim 1, wherein the material having a work function of less than or equal to about 4.0 eV is at least one of ytterbium (Yb), samarium (Sm), lanthanum (La), yttrium (Y), calcium (Ca), strontium (Sr), cesium (Cs), ruthenium (Ru), or barium (Ba).

7. The device as claimed in claim 6, wherein the material having a work function of less than or equal to about 4.0 eV is ytterbium (Yb).

8. The device as claimed in claim 1, wherein the second auxiliary layer includes an electron injection material.

9. The device as claimed in claim 8, wherein the electron injection material is at least one of LiF, NaF, NaCl, CsF, BaO, lithium quinolate, or a combination thereof.

10. The device as claimed in claim 8, wherein the material having a work function of less than or equal to about 4.0 eV and the electron injection material are included in a weight ratio of about 100:1 to about 1:100.

11. The device as claimed in claim 1, wherein the second auxiliary layer has a thickness of about 5 Å to about 50 Å.

12. The device as claimed in claim 1, wherein the magnesium is in an amount of less than or equal to about 30% by volume based on a total amount of the alloy.

13. The device as claimed in claim 12, wherein the magnesium is included in an amount of about 5% by volume to about 30% by volume based on the total amount of the alloy.

14. The device as claimed in claim 1, wherein a mixing ratio of the magnesium and silver is about 1:8 to about 1:12.

15. The device as claimed in claim 1, wherein the first electrode has a thickness of about 30 Å to about 300 Å.

16. The device as claimed in claim 1, wherein the first electrode has light transmittance of about 50% to about 90% at a wavelength of about 500 nm to about 600 nm.

17. An organic light emitting diode, comprising
a first electrode;
a second electrode facing the first electrode;
an emission layer between the first and second electrodes;
a first auxiliary layer between the first electrode and emission layer, and
a second auxiliary layer between the first electrode and first auxiliary layer, wherein the second auxiliary layer includes an inorganic material and wherein the second auxiliary layer includes a material having a work function of less than or equal to about 4.0 eV.

18. The diode as claimed in claim 17, wherein the first electrode includes a silver-magnesium alloy having a greater content of silver than magnesium.

19. The diode as claimed in claim 17, wherein the material having a work function of less than or equal to about 4.0 eV is at least one of ytterbium (Yb), samarium (Sm), lanthanum (La), yttrium (Y), calcium (Ca), strontium (Sr), cesium (Cs), ruthenium (Ru), or barium (Ba).

20. The diode as claimed in claim 17, wherein the first auxiliary layer includes an organic material.
